(19) United States
(12) Patent Application Publication
(10) Pub. No.: US 2025/0006682 A1
(43) Pub. Date: Jan. 2, 2025

(54) SEMICONDUCTOR PACKAGES WITH MULTIPLE TYPES OF SOLDER BALLS

(71) Applicants: JCET Management Co., Ltd., Shanghai (CN); STATS ChipPAC Pte. Ltd., Singapore (SG)

(72) Inventors: Zhan YING, Shanghai (CN); Kai LIU, Jiangyin (CN); Yaqin WANG, Jiangyin (CN)

(21) Appl. No.: 18/740,608

(22) Filed: Jun. 12, 2024

(30) Foreign Application Priority Data
Jun. 30, 2023 (CN) 202310801136.1

(51) Int. Cl. H01L 23/00; H01L 23/31; H01L 23/373; H01L 23/498; H01L 25/065

(52) U.S. Cl. CPC H01L 24/14; H01L 23/373; H01L 23/49816; H01L 23/562; H01L 23/3107; H01L 25/0655; H01L 2224/14505; H01L 2224/14519; H01L 2924/3511

(57) ABSTRACT

A semiconductor package comprise: a package substrate having a front surface and a rear surface, wherein the package substrate comprises: a set of front conductive patterns formed on the front surface; a set of rear conductive patterns formed on the rear surface; and a set of interconnects electrically coupling the set of front conductive patterns with the set of rear conductive patterns, respectively; at least one electronic component mounted on the front surface of the package substrate and electrically coupled to the set of front conductive patterns via a set of front solder balls; a set of rear solder balls electrically connected to the set of rear conductive patterns, respectively; wherein the set of front solder balls comprises one or more first-type solder balls and one or more second-type solder balls, and the set of rear solder balls comprises one or more first-type solder balls and one or more second-type solder balls; and wherein the first-type solder balls of the set of front solder balls are electrically coupled to the first-type solder balls of the set of rear solder balls.

### TECHNICAL FIELD

The present application generally relates to semiconductor technologies, and more particularly, to a semiconductor package with multiple types of solder balls.

### BACKGROUND OF THE INVENTION

The wiring used for interconnection within a semiconductor chip is extremely fine, being of the order of a few microns, or less, in width. The ability to form such wires has made possible for semiconductor chips containing millions or more interconnected components. At some point, however, contacts are required between the chips and the outside world where working to such small tolerances of wiring is not possible.

In order for connecting semiconductor chips to external devices or systems, printed circuit boards (PCB), interposers, or other similar substrates are widely used for mounting the chips thereon, thereby forming semiconductor packages having bigger sizes. The wiring on a PCB is much coarser than on a chip, being typically measured in millimeters. It is not practical to connect chip wiring directly to PCB wiring. Therefore, an intermediate structure, capable of handling both ends of this wire-width spectrum, is needed.

An example of such a structure is a ball grid array (BGA). BGA packaging technology is a surface mounting technology applied to integrated circuits, which is commonly used to permanently fix devices such as microprocessors. The BGA package is an array on the bottom of a package substrate, and solder balls are used as input/output (I/O) terminals of the circuits and connected to a PCB.

The solder ball has the function of signal conduction, electrical connection, and heat conduction. In the existing BGA package, the solder balls on the back side of the package substrate are generally the same. The larger the solder ball, the stronger the heat transfer capability. However, at the same time, the larger the solder ball, the larger the substrate area occupied, which is contrary to the high density and high pin output of the BGA.

Therefore, a need exists for further improvement to semiconductor packages.

### SUMMARY OF THE INVENTION

An objective of the present application is to provide a package structure with improved heat dissipation efficiency.

According to an aspect of the present application, a semiconductor package is disclosed. The semiconductor package comprises: a package substrate having a front surface and a rear surface, wherein the package substrate comprises: a set of front conductive patterns formed on the front surface; a set of rear conductive patterns formed on the rear surface; and a set of interconnects electrically coupling the set of front conductive patterns with the set of rear conductive patterns, respectively; at least one electronic component mounted on the front surface of the package substrate and electrically coupled to the set of front conductive patterns via a set of front solder balls; a set of rear solder balls electrically connected to the set of rear conductive patterns, respectively; wherein the set of front solder balls comprises one or more first-type solder balls and one or more second-type solder balls, and the set of rear solder balls comprises one or more first-type solder balls and one or more second-type solder balls; and wherein the first-type solder balls of the set of front solder balls are electrically coupled to the first-type solder balls of the set of rear solder balls.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1 to 3 illustrate a semiconductor package according to an embodiment of the present application. FIG. 1 is a cross-sectional view of the package. FIG. 2 is a front view of the package substrate and FIG. 3 is a rear view of the package substrate.

FIGS. 4 and 5 illustrate a semiconductor package according to another embodiment of the present application. FIG. 4 is a cross-sectional view of the package substrate. FIG. 5 is a rear view of the package substrate.

FIGS. 6 and 7 illustrate a semiconductor package according to another embodiment of the present application. FIG. 6 is a cross-sectional view of the package substrate. FIG. 7 is a rear view of the package substrate.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The inventors of the present application have found that, due to mismatch in thermal expansion coefficient between semiconductor chips, packaging adhesive, package substrates and other structures of semiconductor packages under continuous thermal load conditions generated by the semiconductor chips, inter-layer thermal stress and thermal deformation inside the semiconductor packages may occur. Stripping stress and shear stress at structural interfaces within semiconductor packages may lead to delamination and warping of the package structures, even cause failures to the semiconductor packages. For example, in some cases, the solder balls at four corners of a semiconductor package could break easily in case of drop or collision.

The above phenomenon may be less likely for packages with smaller solder balls. However, if smaller solder balls are used, it is not beneficial for heat conduction from semiconductor chips to the external space through the packaging structures. As electronic products continue to shrink in size or integrate therein more components, the formation of smaller semiconductor packaging structure with more functions is important. However, as the semiconductor package volume decreases and the power increases, the calorific value per unit volume of the chip increases sharply. If the temperature is too high, it is also likely to induce failure, breakdown, junction failure, and metallization failure. When heat is generated by the semiconductor chips, most of the heat is transferred to the outside of the semiconductor packages through their package structures. But the package structures are generally made of epoxy resin and filler and other low thermal conductivity materials. Therefore, when the semiconductor chips, due to a long time of operation, produce a lot of heat, the package structures may not be able to conduct heat in time, resulting in the heat being trapped in the chips.

In order to resolve at least one of the problems described above, a multiple-type solder ball array is proposed by the inventors of the present application to interconnect semiconductor chips with package substrates and/or the package substrates with external devices. For example, solder balls with copper cores or similar higher thermal conductivity materials may be used, as well as solder balls made of lower thermal conductivity soldering material such as tin. In some cases, the high thermal conductivity solder balls may be formed across a package substrate, which may establish thermal paths with improved heat dissipation capability for the semiconductor package, thereby reducing significantly the risk of failures of the semiconductor packages.

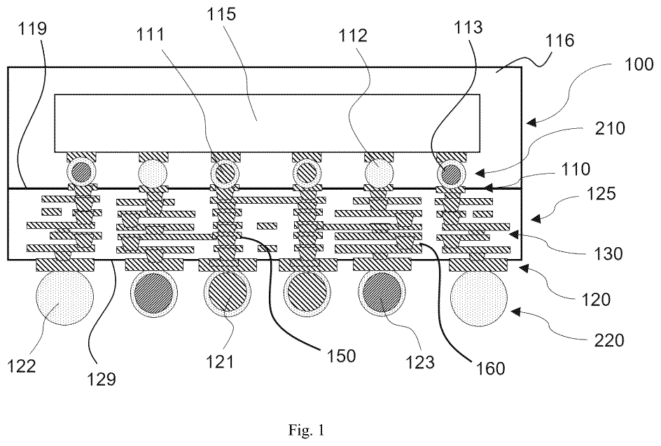

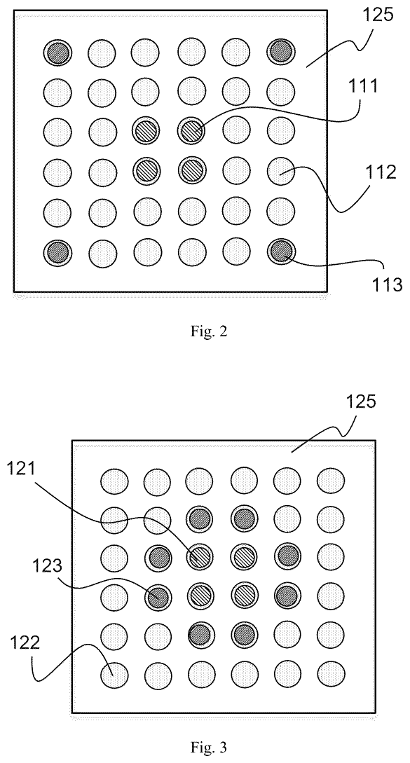

FIGS. 1 to 3 illustrate a semiconductor package 100 according to an embodiment of the present application. FIG. 1 is a cross sectional view of the semiconductor package 100, FIG. 2 is a front view of a package substrate of the semiconductor package 100 and FIG. 3 is a rear view of the package substrate of the semiconductor package 100.

As shown in FIG. 1, the semiconductor package 100 includes a package substrate 125 having a front surface 119 and a rear surface 129. The package substrate 125 may include one or more insulating layers, which may be interleaved with one or more conductive layers. It can be appreciated that the package substrate 125 can include any number of conductive and insulating layers interleaved over each other. The insulating layer may include ceramic, plastic, glass, or any other suitable insulating materials. The conductive layers, along with other internal conductive structures such as vias, form interconnects 130 embedded within the package substrate 125. The interconnects 130 may be formed of copper, for example.

The package substrate 125 further includes a set of front conductive patterns 110, such as contact pads, formed on the front surface 119, and a set of rear conductive patterns 120, such as contact pads, formed on the rear surface 129. The front and rear conductive patterns may be respective end surfaces of a set of interconnects 130 embedded in the insulating layer of the package substrate 125, which are exposed from either the front surface 119 or the rear surface 129. The set of interconnects 130 can electrically couple the set of front conductive patterns 110 with the set of rear conductive patterns 120, respectively. In some embodiments, the interconnects 130 may include conductive wiring or vias to route signals through the insulating layer, as aforementioned.

At least one electronic component 115 is mounted on the front surface 119 of the package substrate 125. The electronic component or components can be in the form of a semiconductor die or dice. In some embodiments, the at least one electronic component 115 may include one or more digital chips, analog chips or mixed signal chips, such as application-specific integrated circuit (“ASIC”) chips, sensor chips, wireless and radio frequency (RF) chips, memory chips, logic chips, or voltage regulator chips. In some other embodiments, the at least one electronic component 115 may also include one or more passive electrical components such as resistors, capacitors, inductors, etc. In the embodiment shown in FIG. 1, the electronic component 115 is a semiconductor die or chip with multiple input/output ports, each of which is required to be electrically coupled to an external device for signal or power transmission.

The semiconductor package 100 further includes a set of front solder balls 210 and a set of rear solder balls 220, which are electrically connected to the set of front and rear conductive patterns 110, 120, respectively. The electronic component 115 is electrically coupled to the set of front conductive patterns 110 via the set of front solder balls 210 to establish electrical connection with the package substrate 125.

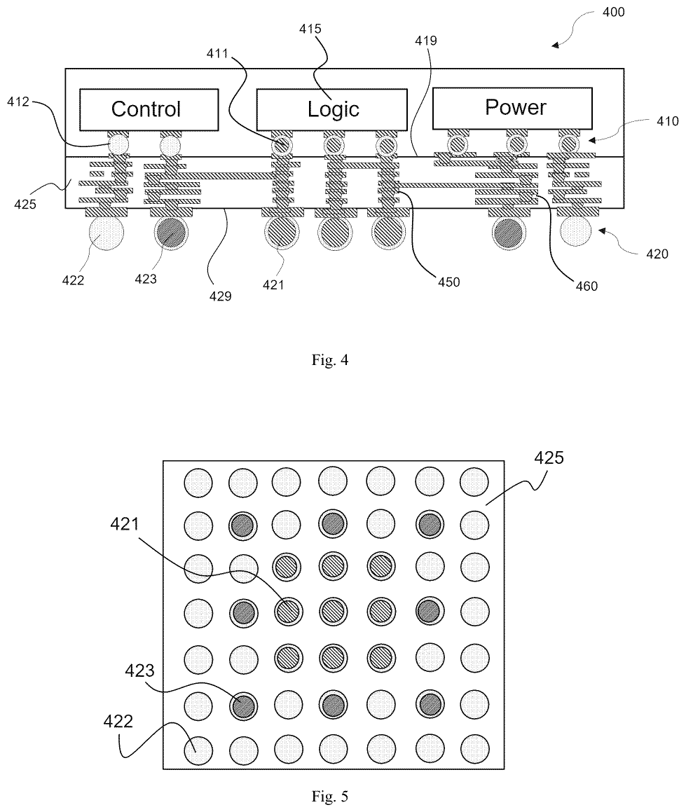

In particular, the front and rear solder balls 210 and 220 can be deposited on the package substrate 125 in the form of balls or similar structures. As can be seen from FIG. 1, a first pitch between two adjacent solder balls of the front solder balls 210 can be increased to a second pitch between two adjacent solder balls of the rear solder balls 220, because there is more space on the package substrate 125, especially when the interconnects 130 can provide for redistribution of the wiring. Accordingly, the set of rear solder balls 220 may have a size that is greater than a size of the set of front solder balls 210. In other words, the layout of the solder balls on the rear surface 129 is exaggerated than the layout of the solder balls on the front surface 119. The bigger layout of solder balls allows for possibility of better heat dissipation. In some embodiments, the number of solder balls in the set of front solder balls 210 may be equal to the number of solder balls in the set of rear solder balls 220 as illustrated in the embodiments of FIGS. 1 to 3. In a variant, for example as illustrated further in the embodiment of FIGS. 4 and 5, the number of solder balls in the set of front solder balls 410 and the number of solder balls in the set of rear solder balls 420 are different, for example, because two or more of the solder balls in one set may be coupled to a solder ball in the other set.

The set of front solder balls 210 include at least two types of solder balls, i.e., a plurality of first-type solder balls 111 and a plurality of second-type solder balls 112. Similarly, the set of rear solder balls 220 include at least two types of solder balls, i.e., a plurality of first-type solder balls 121 and a plurality of second-type solder balls 122. In the illustrated embodiments, the first-type solder balls 111, 121 can include a copper core and a soldering material coating outside the copper core, while the second-type solder balls 112, 122 can be made solely of the soldering material such as tin. In some other embodiments, the first-type solder balls 111, 121 may be made of other soldering material(s) that have better thermal conductivity. Compared to the second-type solder balls 112, 122, the first-type solder balls 111, 121 may have a greater thermal and electrical conductivity, therefore allowing better heat dissipation and lower electrical resistance. In some embodiments, the first-type solder balls 111, 121 are preferably located in a region of the electronic component 115 that consumes more power and generate more heat than the other regions of the electronic component 115, because more heat is required to be conducted through the first-type solder balls 111, 121. In some other embodiments, the first-type solder balls 111, 121 are preferably located in a region of the electronic component 115 that needs better heat dissipation than the other regions of the electronic component 115. For example, the first-type solder balls 111, 121 are at least located in a central region of the package substrate 125, which may have the longest heat dissipation path than the other regions (e.g., peripheral regions) of the package substrate 125. Furthermore, as mentioned above, the first-type solder ball 121 on the back side of the package substrate 125 can further improve the heat transfer capability of the semiconductor package 100, especially for those regions that require better heat dissipation.

Although thermal conductivity may be a factor desired to be considered for the multiple types of solder balls mounted on the package substrate 125, some other factors or characteristics may be considered as well. In some embodiments, at least one set of the sets of front solder balls 210 and the set of rear solder balls 220 may further include one or more third-type solder balls, which may be made at least partially of a material having a thermal expansion coefficient smaller than the first-type solder balls and the second-type solder balls. For example, in the embodiment shown in FIG. 1, each set of the set of front solder balls 210 and the set of rear solder balls 220 includes a plurality of third-type solder balls 113, 123. The third-type solder balls 113 and 123 both include a resin core coated by a soldering material. Such a type of solder balls allows to provide mechanical support and compensate mechanical stress produced within the semiconductor package 100, for example due to thermal expansion, because the resin core may compensate mechanical stress significantly. In some embodiments, the third-type solder balls are for example arranged in a region of the package substrate 125 where the density of the interconnects 130 is higher than in other regions, because denser interconnects needs to compensate greater mechanical stress. For example, as shown in FIGS. 2 and 3, the third-type solder balls 123 of the set of rear solder balls 220 may be arranged surrounding the first-type solder balls 121 of the set of rear solder balls 220. Accordingly, the second-type solder balls 122 may be arranged at the corners surrounding the first-type solder balls 121 and the third-type of solder balls 123. In one embodiment, the third-type solder balls 113 of the set of front solder balls 210 are arranged at the corners of the electronic component 115 to compensate mismatch in thermal expansion between the electronic component 115 and the package substrate 125. In addition, the third-type solder balls 113 at the corners of the electronic component 115 can maintain a proper distance between the electronic component 115 and the package substrate 125 after a reflow process of the solder balls, thereby allowing the passage of the encapsulant material and avoid the formation of voids or cavities in the encapsulant layer. In some embodiments, the third-type solder balls may be located in a region below the electronic component 115 where a maximum mechanical stress is to be produced during use of the semiconductor package 100. Furthermore, the second-type solder balls 112, 122 of the set of front or rear solder balls may be formed at the other positions of the package substrate 125 to complete a BGA structure, for example.

In the embodiment shown in FIGS. 1 to 3, each solder ball of the rear solder balls 220 is coupled to at least one solder ball of the front solder balls 210 via at least a pair of front and rear conductive patterns 110, 120 and interconnects 130 therebetween. In the embodiment of FIG. 1, each first-type solder ball 121 of the set of rear solder balls 220 is aligned vertically with one first-type solder ball 111 of the set of front solder balls 210, when viewed in a direction perpendicular to the front or rear surface 119, 129 of the package substrate 125. Accordingly, an interconnect path 150 connecting each first-type solder ball 121 of the set of rear solder balls 220 to one first-type solder ball 111 of the set of front solder balls 210 is substantially perpendicular to the package substrate 125. In this way, the interconnect path 150 connecting a first-type solder ball 121 of the set of rear solder balls 220 to a first-type solder ball 111 of the set of front solder balls 210 has a shorter total length of wiring or vias, and preferably a greater width, than other interconnect paths 160 interconnecting a second-type or a third-type solder ball of the set of rear solder balls 220 to a solder ball of the set of front solder balls 210, or interconnecting a second-type or a third-type solder ball of the set of front solder balls 210 to a solder ball of the set of rear solder balls 220. The interconnect path 150 has accordingly a better thermal and electrical conductivity, which may be helpful for heat dissipation for the electronic component 115 that produce more heat during operation. It can be appreciated that, in some alternative embodiments, the interconnect path 150 connecting each first-type solder ball 121 of the set of rear solder balls 220 to one first-type solder ball 111 of the set of front solder balls 210 may not be perpendicular to the package substrate 125, because of the routing of the interconnects 130 in the package substrate 125 or other considerations. Nevertheless, the use of first-type solder balls 111 and 121 on both sides of the package substrate 125 allows for better heat transfer capability.

The semiconductor package 100 may further include at least one encapsulant layer 116 extending at least partially on the substrate 125 and covering the at least one electronic component 115. The encapsulant layer 116 may provide protection for the electronic component 115. In some embodiments, a shielding layer (not shown) may be further formed over the encapsulant layer 116 for electromagnetic interference shielding purpose.

FIGS. 4 and 5 illustrate a semiconductor package 400 according to another embodiment of the present application. As shown in FIGS. 4 and 5, three electronic components 415 are encapsulated within the semiconductor package 400. In particular, the electronic component 415 includes a plurality of semiconductor dice, namely a control chip, a logic circuit chip, and a power chip.

In the embodiment, a set of front solder balls 410 is mounted on a front surface of a package substrate 425. The set of front solder balls 410 include, at a central region of the package substrate 425 below the logic circuit chip, a plurality of first-type solder balls 411, for electrical and thermal conduction, coupled respectively to a first-type solder ball 421 belonging to a set of rear solder balls 420 which are mounted on a rear surface of the package substrate 425. The set of front solder balls 410 further includes, below the power chip, a plurality of first-type solder balls 411, for high current transmission, coupled respectively to second-type and third-type solder balls 422 and 423 belonging to the set of rear solder balls 420. The set of front solder balls 410 further includes, below the control chip, a plurality of second-type solder balls 412, for weak current transmission, coupled respectively to second-type and third-type solder balls 422 and 423 belonging to the set of rear solder balls 420. As illustrated in FIG. 4, the interconnect path 450 connecting each first-type solder ball 421 of the set of rear solder balls 420 to a corresponding first-type solder ball 411 of the set of front solder balls 410 is substantially perpendicular to the front surface 419 or the rear surface 429 of the package substrate 425, and thus may be shorter than another interconnect path 460 connecting a second-type or third-type solder ball 422, 423 of the set of rear solder balls 420 to a solder ball of the set of front solder balls 410. As shown in FIG. 5, the first-type solder balls 421 of the set of rear solder balls 420 are surrounded by the second-type solder balls 422 and the third-type solder balls 423 of the set of rear solder balls 420 distributed at intervals. The second-type solder balls 422 may be formed at the other positions in a region of the package substrate 425 to complete the BGA structure.

In some embodiments, the electronic components encapsulated in the semiconductor packages may be other components such as chip-lets or other similar smaller packages.

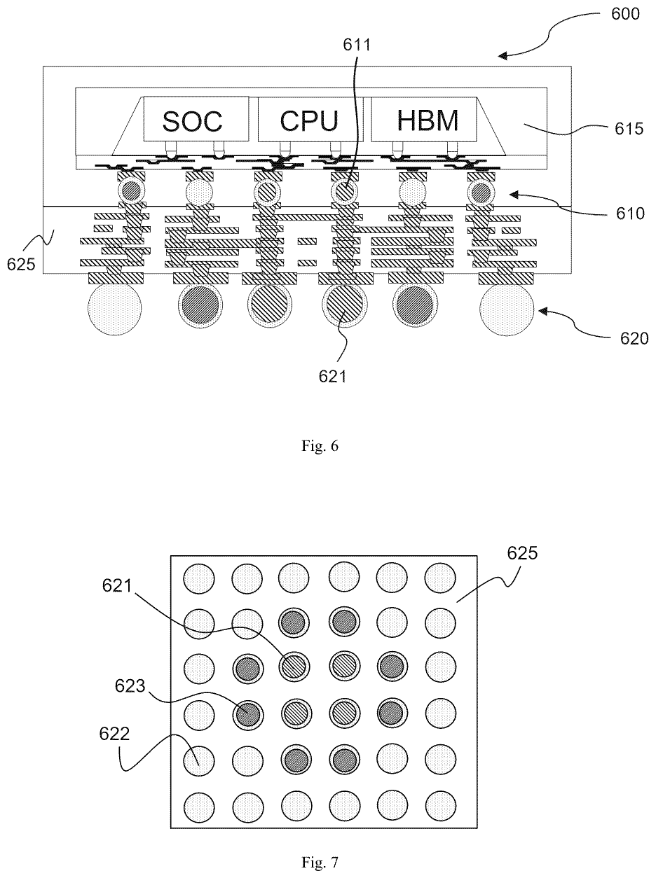

FIGS. 6 and 7 illustrate a semiconductor package 600 according to another embodiment of the present application. As shown in FIGS. 6 and 7, an electronic component 615 which in the form of a chip-let is mounted on a front surface of a package substrate 625 of the semiconductor package 600. The chip-let may include, as illustrated, several modules, for example a System of Chip (SoC), a High-bandwidth Memory (HBM), and a CPU module.

Similar as the embodiment shown in FIGS. 4 and 5, different types of solder balls may be mounted on the front and rear surfaces of the package substrate 625 depending on different modules of the electronic component 615. In particular, a set of front solder balls 610 are mounted on a front surface of the package substrate 625. The front solder balls 610 include, below a central region CPU of the electronic component 615 (chip-let), a plurality of first-type solder balls 611 coupled respectively to a first-type solder ball 621 belonging to the set of rear solder balls 620 to provide better thermal and electrical conductivity. The first-type solder balls 611 and 621 may include a copper core and a soldering material coating outside the copper core. Other types of solder balls such as second-type solder balls made of tin and third-type solder ball including a resin core and a soldering material coating outside the resin core may be mounted on the package substrate 625, in a manner similar to the semiconductor package 100 shown in FIGS. 1 to 3, which will not be elaborated herein.

While the semiconductor package of the present application is described in conjunction with corresponding figures, it will be understood by those skilled in the art that modifications and adaptations to the semiconductor package may be made without departing from the scope of the present invention.

The discussion herein includes numerous illustrative figures that show various portions of a semiconductor package. For illustrative clarity, such figures do not show all aspects of each example semiconductor package. Any of the example semiconductor packages provided herein may share any or all characteristics with any or all other semiconductor packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a package substrate having a front surface and a rear surface, wherein the package substrate comprises:
a set of front conductive patterns formed on the front surface;
a set of rear conductive patterns formed on the rear surface; and
a set of interconnects electrically coupling the set of front conductive patterns with the set of rear conductive patterns, respectively;
at least one electronic component mounted on the front surface of the package substrate and electrically coupled to the set of front conductive patterns via a set of front solder balls;
a set of rear solder balls electrically connected to the set of rear conductive patterns, respectively;
wherein the set of front solder balls comprise one or more first-type solder balls and one or more second-type solder balls, and the set of rear solder balls comprises one or more first-type solder balls and one or more second-type solder balls; and
wherein the first-type solder balls of the set of front solder balls are electrically coupled to the first-type solder balls of the set of rear solder balls.

2. The semiconductor package of claim 1, wherein the first-type solder balls have heat and electrical conductivity greater than the second-type solder balls.

3. The semiconductor package of claim 2, wherein the first-type solder balls comprises a metal core and a soldering material coating outside the metal core.

4. The semiconductor package of claim 1, wherein each first-type solder ball of the set of rear solder balls is aligned with one first-type solder ball of the set of front solder balls vertically when viewed in a direction perpendicularly to the front surface of the package substrate.

5. The semiconductor package of claim 4, wherein each first-type solder ball of the set of rear solder balls is electrically coupled to one first-type solder ball of the set of front solder balls through an interconnect path that is substantially perpendicular to the package substrate.

6. The semiconductor package of claim 1, wherein each first-type solder ball of the set of rear solder balls is electrically coupled to one first-type solder ball of the set of front solder balls through an interconnect path having a length equal to or shorter than that of any other interconnect path electrically coupling one second-type solder ball of the set of front solder balls to one solder ball of the set of rear solder balls, or electrically coupling one second-type solder ball of the set of rear solder balls to one solder ball of the set of front solder balls.

7. The semiconductor package of claim 1, wherein each first-type solder ball of the set of rear solder balls is electrically coupled to one first-type solder ball of the set of front solder balls through an interconnect path having a thermal and electrical conductivity equal to or greater than that of any other interconnect path electrically coupling one second-type solder ball of the set of front solder balls to one solder ball of the set of rear solder balls, or electrically coupling one second-type solder ball of the set of rear solder balls to one solder ball of the set of front solder balls.

8. The semiconductor package of claim 1, wherein the set of front solder balls further comprise one or more third-type solder balls that have a thermal expansion coefficient smaller than the first-type solder balls and the second-type solder balls.

9. The semiconductor package of claim 8, wherein the one or more third-type solder balls of the set of front solder balls are located outer than the one or more second-type solder balls of the set of front solder balls.

10. The semiconductor package of claim 8, wherein the one or more third-type solder balls are located in a region below the electronic component where a maximum mechanical stress is to be produced during use of the semiconductor package.

11. The semiconductor package of claim 1, wherein the set of rear solder balls further comprise one or more third-type solder balls that have a thermal expansion coefficient smaller than the first-type solder balls and the second-type solder balls.

12. The semiconductor package of claim 11, wherein the one or more third-type solder balls of the set of rear solder balls are located outer than the one or more first-type solder balls of the set of rear solder balls.

13. The semiconductor package of claim 1, wherein the one or more first-type solder balls of the set of front solder balls are located in a region below the electronic component that consumes more power than the other region of the electronic component.

14. The semiconductor package of claim 1, wherein the electronic component is a semiconductor die.

15. The semiconductor package of claim 1, wherein the electronic component is a semiconductor package with at least two semiconductor dice encapsulated therein.

16. The semiconductor package of claim 15, wherein the semiconductor package is a chip-let package.
